(19) United States
(12) Patent Application Publication
(10) Pub. No.: US 2025/0042721 A1
(43) Pub. Date: Feb. 6, 2025

(54) MEMS COMPONENT WITH A MEMBRANE SPRING AND METHOD FOR PRODUCING A MEMBRANE SPRING

(71) Applicant: Robert Bosch GmbH, Stuttgart (DE)

(72) Inventor: Stefan Pinter, Reutlingen (DE)

(21) Appl. No.: 18/786,667

(22) Filed: Jul. 29, 2024

(30) Foreign Application Priority Data
Aug. 4, 2023 (DE) 10 2023 207 523.7

(51) Int. Cl. B81B 3/00; B81C 1/00; F16F 3/087

(52) U.S. Cl. CPC B81B 3/007; B81B 3/0027; B81C 1/00658; F16F 3/0873; B81B 2203/0127; B81B 2203/019; B81C 2201/0132; B81C 2201/0143; B81C 2201/0157; F16F 2224/0275; F16F 2226/023; F16F 2226/04; F16F 2226/048; F16F 2228/066; F16F 2228/08; F16F 2230/0005; F16F 2238/022

(57) ABSTRACT

A MEMS component. The MEMOS component includes a micromechanical membrane spring including first and second membrane spring elements with an at least regional two-dimensional curvature. The first membrane spring element is mechanically coupled to the second membrane spring element such that a resulting spring force of the membrane spring is imparted by the first and second membrane spring elements. The membrane spring is integrated into a layer structure of the MEMS component such that the resulting spring force of the membrane spring acts substantially in the layer sequence direction of the layer structure. A device for preloading the membrane spring is configured to set an operating point of the membrane spring with respect to the spring characteristic curve using permanent elastic deflection of the membrane spring, such that the operating point is in an approximately linear spring characteristic curve range of the membrane spring with a slight gradient.

### FIELD

The present invention relates to a membrane spring, in particular a micromechanical membrane spring for a MEMS component (MEMS: microelectromechanical system, microsystem), such as a MEMS transducer. The present invention furthermore relates to a MEMS component, in particular a MEMS sensor or MEMS actuator, having such a membrane spring. Furthermore, methods for producing membrane springs for MEMS components are provided.

### BACKGROUND INFORMATION

A fundamental difficulty of many MEMS sensors is that conventional, mechanically elastically deformable elements, such as beams or membranes, are typically only slightly deflected under the forces acting on them. The small deflections result in only low electrical signals generated by transducer elements. With MEMS actuators, only limited forces can thus usually be generated for the desired large deflections. In principle, it is technologically possible to produce very soft beams or membranes with the desired dimensions for use in MEMS components, but, due to their fineness, the structures produced can easily be destroyed during the production process or in use, for example due to an overload.

The mechanical stiffness of elastically deformable elements is described by the spring constant or spring characteristic curve. In the field of mechanics, springs or spring elements of different designs with different spring characteristic curves, which can, for example, have a linear, progressive, degressive-progressive, degressive-horizontal-progressive or degressive-negative-progressive course, are sufficiently known. Within the framework of this disclosure, linear spring characteristic curves are referred to as “nonlinear” in parts. Usually, MEMS sensors and MEMS actuators are designed to operate in a linear stiffness range.

In the case of mechanical springs, it is generally conventional to change the course of the spring characteristic curve in wide ranges by structural modifications, for example by a mechanical combination of spring elements with different spring characteristic curves. For example, a slotted disk spring, or a tongue disk spring, generally has an increased spring travel and a reduced spring force in comparison to a conventional disk spring. The production of such structures within the framework of microelectromechanical systems (MEMS) is largely unknown.

Conventional mechanical spring elements are not necessarily suitable for use in MEMS components. Disk springs are typically not clamped inside or outside, i.e., they are mounted loosely. When they are deformed, friction occurs at these points, which is often undefined and excludes them from use in a MEMS sensor or MEMS actuator.

U.S. Patent Application Publication No. US 2020/0284940 A1 discloses a MEMS gravimeter with a spring-mass system, which comprises a spring with a partly negative stiffness (also rigidity) and a further spring with a positive stiffness. The spring with the partly negative stiffness is provided by a one-dimensionally curved beam whose opposite ends are firmly anchored.

### SUMMARY

The present invention aims to provide micromechanical spring elements and methods for their production, which are particularly suitable for use in MEMS components, in particular MEMS actuators and/or MEMS sensors.

The aforementioned object may be achieved by features of the present invention. Advantageous configurations of the present invention are disclosed herein.

According to an example embodiment of the present invention, a MEMS component, in particular a MEMS actuator or sensor, comprises a micromechanical membrane spring or a micromechanical membrane spring element with an at least regional, convex or concave, two-dimensional curvature. The membrane spring is suitable for imparting a spring force in the layer sequence direction of a layer composite of the MEMS component into which the membrane spring can be integrated.

According to an example embodiment of the present invention, the structure of the micromechanical membrane spring is two-part and comprises a first membrane spring element, preferably with a linear characteristic curve, and a second membrane spring element, preferably with a nonlinear characteristic curve. The second membrane spring element has the at least regionally convex or concave, two-dimensional curvature and is mechanically coupled to the first membrane spring element in such a way that the spring forces imparted by the first and the second membrane spring element act as a resulting spring force in the layer sequence direction of a layer structure of the MEMS component. For this purpose, the membrane spring is integrated into the layer structure of the MEMS component.

By structural modifications of the first and/or second membrane spring element, the spring characteristic of the membrane spring can be adapted to specific requirements of the application. In particular, it is provided in embodiments for a first membrane spring element with a linear spring characteristic curve and a second membrane spring element with a nonlinear spring characteristic curve to be mechanically coupled to one another, preferably in such a way that the resulting spring characteristic curve has a slight gradient in a partial region.

According to an example embodiment of the present invention, the MEMS component comprises a device for preloading the membrane spring. The preloading device is configured to set a permanent elastic deflection of the membrane spring, in particular in such a way that an operating point is set with respect to the resulting spring characteristic curve of the membrane spring. Preferably, the membrane spring is preloaded in such a way that the operating point is in an at least approximately linear spring characteristic curve range of the membrane spring with a slight gradient. For this purpose, the membrane spring is slightly deflected from its rest position, in particular by the application of force. With suitable dimensioning, in particular of the first and/or second membrane spring element, the high spring stiffness which the membrane spring as a spring combination element preferably has in the non-deflected state can be significantly reduced by the preloading so that a linear range of the spring characteristic curve with a small positive or negative gradient can in particular be achieved. This in particular makes it possible to produce MEMS sensors and actuators in silicon, which are very robust against destruction by an overload during production. Preloading also reduces the stiffness of the membrane spring during operation so that large movement amplitudes for detection by sensors and/or for actuation are made possible.

In advantageous exemplary embodiments of the present invention, for generating the resulting spring force, the first membrane spring element is mechanically connected in a central region of the second membrane spring element. Preferably, the first membrane spring element is connected in a curved region of the second membrane spring element and/or in the region of a maximum spring travel of the second membrane spring element in order to provide a membrane spring element with the desired spring characteristic along the resulting spring travel.

In advantageous embodiments of the membrane spring of the present invention, a membrane plane of the first membrane spring element is arranged in parallel with a membrane plane of the second membrane spring element. Preferably, the first membrane spring element is designed to generate a spring force which acts in a direction perpendicular to the membrane plane and follows a linear characteristic curve. The second membrane spring element is preferably designed to generate a spring force which follows a nonlinear spring characteristic curve in the direction perpendicular to the membrane plane.

In exemplary embodiments of the present invention, the first membrane spring element and/or the second membrane spring element is substantially annular. The first membrane spring element and the second membrane spring element are preferably arranged concentrically with one another. In alternative embodiments, the first and/or second membrane spring element is substantially designed as a lens-shaped raised structure.

Preferably, according to an example embodiment of the present invention, the first and/or second membrane spring element is designed to be rotationally symmetrical about an axis of symmetry and is arranged concentrically with respect to this axis of symmetry.

Preferably, according to an example embodiment of the present invention, the membrane spring consists at least in part, particularly preferably completely, of silicon. In particular, the first and/or the second membrane spring element can consist of silicon. Silicon is a material with very good elastic properties. The spring properties of such a membrane spring are very homogeneous and stable due to the high purity of the material. In general, membrane springs made of silicon do not show significant plastic deformation up to a temperature of several hundred degrees Celsius. Silicon can be precisely structured using established MEMS processes and makes parallelized production of a large number of miniaturized components on a wafer at low cost possible.

In advantageous embodiments of the present invention, the preloading device comprises at least one cavity which is subjected to negative pressure or positive pressure and which is at least regionally delimited by the membrane spring, in particular at least regionally by the first and/or second membrane spring element. Subjecting the cavity to pressure causes a force to be applied to the membrane spring or to at least one of the membrane spring elements so that a pneumatic preloading of the membrane spring as a whole and, accordingly, a reduced spring stiffness after joint preloading can be set. This makes it possible to implement a wide range of applications for MEMS sensors and actuators.

Preferably, according to an example embodiment of the present invention, the first membrane spring element is mechanically connected at an outer circumference to the layer structure and to the second membrane spring element in such a way that a functional membrane suspended on the inner circumference of the first membrane spring element is movably guided along a spring path parallel to the first direction.

In preferred embodiments of the present invention, the second membrane spring element is mechanically connected at its inner circumference and outer circumference to the layer structure. The second membrane spring element is mechanically connected to the first membrane spring element in a two-dimensionally curved region located between the inner circumference and the outer circumference.

The production of a curved membrane spring, in particular made of silicon, represents a major challenge in terms of process technology since it cannot be implemented using conventional MEMS planar processes and is therefore difficult to integrate into the process sequences commonly used for the production of MEMS components.

In the following, methods for producing two-dimensionally convexly or concavely curved membrane springs, in particular made of silicon, are disclosed.

Within the framework of this disclosure, two-dimensionally curved membrane springs or membrane spring elements in particular refer to those that have a curvature with respect to two mutually orthogonal directions at least in one region of their surface and are thus to be distinguished from spring elements which are only curved in one dimension, such as beam springs.

An at least regionally two-dimensionally convexly or concavely curved membrane spring can, for example, be produced in an additive, subtractive or forming manufacturing step.

According to a variant of the production method according to the present invention, in a forming manufacturing step, a layer which is at least partly exposed in the layer structure, in particular of the MEMS component already described above, is subjected to pressure and plastically deformed.

Preferably, the at least partly exposed layer is heated locally during the plastic deformation, in particular by means of laser radiation, in order to locally limit heating and in particular thus to largely avoid damaging heat input to any heat-sensitive components or structures of the MEMS component.

In advantageous embodiments of the present invention, the first membrane spring element is mechanically connected to the second membrane spring element by means of laser welding.

In preferred embodiments of the production method of the present invention, for permanent elastic, in particular pneumatic, preloading of the membrane spring, at least one cavity introduced into the layer structure of the MEMS component is subjected to negative pressure or positive pressure and is subsequently sealed in a pressure-tight and gas-tight manner. The cavity is delimited at least regionally by the membrane spring, in particular at least regionally by the first and/or second membrane spring element, so that the membrane spring is deflected by the set pressure difference. The deflection of the membrane spring, in particular for setting a function corresponding to the particular application, preferably takes place at the end of the production process. Preferably, the membrane spring has a spring characteristic curve range with high rigidity in its rest position, i.e., without the influence of external forces. In its rest position, the membrane spring is in a spring characteristic curve range with a large gradient and is thus very robust against destruction by an overload during production. The deflection of the membrane spring preferably takes place in such a way that a flat spring characteristic curve range is achieved and a reduced force is thus required for further deflection of the membrane spring. Depending on the geometry of the curved membrane spring, in particular of the first and/or second membrane spring element, a common spring constant and/or resonance frequency can be varied via the coupled preloading and the membrane spring can thus be structurally adapted to the specific micromechanical application.

According to another variant of the production method of the present invention, the at least regionally convex or concave, two-dimensional curvature of the membrane spring or the membrane spring element is formed in an additive manufacturing step by depositing regionally overlapping layers, in particular made of silicon or polysilicon. Particularly preferred, multiple individual layers are stacked on top of one another and structured appropriately. For example, trenches are etched into an applied layer and are filled with a filler, in particular an oxide, before the subsequent layer is applied.

According to another variant of the production method of the present invention, the at least regionally convex or concave, two-dimensional curvature of the membrane spring is formed in a subtractive manufacturing step by material ablation of a substantially flat substrate, wherein material is removed from opposite end faces of the substrate. The material ablation takes place, for example, by laser ablation or by isotropic etching.

The production of such membrane springs, in particular membrane springs with robust membrane thickness and low spring stiffness after preloading, makes it possible to implement a wide range of applications of MEMS transducers, in particular MEMS sensors and MEMS actuators, such as:
pressure sensors, in particular with a large pressure range;
speakers;
microphones;
(plate) gravimeters, scales;
Z-actuators with a large stroke, for example for focusing optical elements;
energy harvesters;
Helmholtz resonators, in particular as acoustic damping elements;
relays, in particular monostable or bistable relays;
microelectromechanical ultrasonic transducers, in particular PMUTs (piezoelectric micromachined ultrasonic transducers), in which a thin piezoelectric transducer layer is applied to a thin membrane, in particular made of silicon, and the membrane is deflected by the transducer layer.

Further details and advantages of the present invention are explained in more detail below with reference to the exemplary embodiments shown in the figures.

### BRIEF DESCRIPTION OF THE DRAWINGS

FIGS. 1A to 1C show a subtractive production method for producing a two-dimensionally curved membrane spring by means of laser ablation, according to an example embodiment of the present invention.

FIGS. 2A to 2F show a subtractive production method for producing a two-dimensionally curved membrane spring by means of RIE etching, according to an example embodiment of the present invention.

FIGS. 3A and 3B show a subtractive production method for producing a two-dimensionally curved membrane spring by means of a three-dimensional polymer etching mask, according to an example embodiment of the present invention.

FIGS. 4A and 4B show a production method for producing a two-dimensionally curved membrane spring by means of forming, according to an example embodiment of the present invention.

FIGS. 5A to 5E show a production method for producing a two-dimensionally curved membrane spring by means of forming and laser structuring, illustrated in sectional views, according to an example embodiment of the present invention.

FIG. 6 shows the laser treatment for forming the membrane spring in a plan view, according to an example embodiment of the present invention.

FIGS. 7A and 7B show a membrane spring produced according to the method illustrated in FIGS. 5A to 5E, in schematic sectional views, according to an example embodiment of the present invention.

FIGS. 8A to 8G show an additive production method for producing a two-dimensionally curved membrane spring or a two-dimensionally curved membrane spring element, according to an example embodiment of the present invention.

FIGS. 9A to 9L show a production method for producing a membrane spring with coupled membrane spring elements by means of forming, according to an example embodiment of the present invention.

FIGS. 10A and 10B show a membrane spring with coupled membrane spring elements and a device for preloading a functional membrane in a perspective view, according to an example embodiment of the present invention.

FIGS. 11A and 11B show a production method for producing a membrane spring with coupled membrane spring elements produced using additive or subtractive technology, according to an example embodiment of the present invention.

FIG. 12 shows a production method for producing a membrane spring with a large mass on a functional membrane, in particular for use in an energy harvester, according to an example embodiment of the present invention.

### DETAILED DESCRIPTION OF EXAMPLE EMBODIMENTS

Identical or corresponding elements are provided with the same reference signs in all figures.

The exemplary embodiments illustrated in the figures have a rotationally symmetrical, in particular circular or annular, membrane geometry, but it is understood that this is not to be interpreted as restrictive and that deviations are possible.

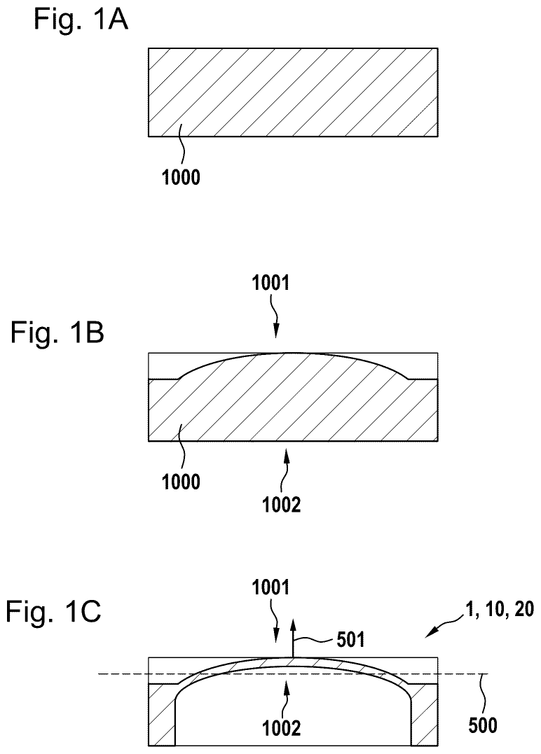

With reference to FIGS. 1A to 6, 8A-8G, 9A-9L, 11A, 11B, and 12, different production methods of two-dimensionally curved membrane springs 1 for a MEMS component 700, in particular of curved membrane springs 1 with a nonlinear spring characteristic curve, two-dimensionally curved membrane springs are described. The two-dimensionally curved membrane spring 1 preferably consists of silicon.

FIGS. 1C, 2F, 7A, 7B, 8G, 9L and 10A and 10B, 11B and 12 show membrane springs 1 which are produced by means of the methods described here and are at least regionally two-dimensionally convexly or concavely curved. The membrane spring 1 is designed to impart a spring force 501 in a first direction 601 substantially perpendicular to a membrane plane 500. Preferably, the membrane spring 1 is designed to impart a spring force 501 in the layer sequence direction of a layer structure 600 of the MEMS component 700.

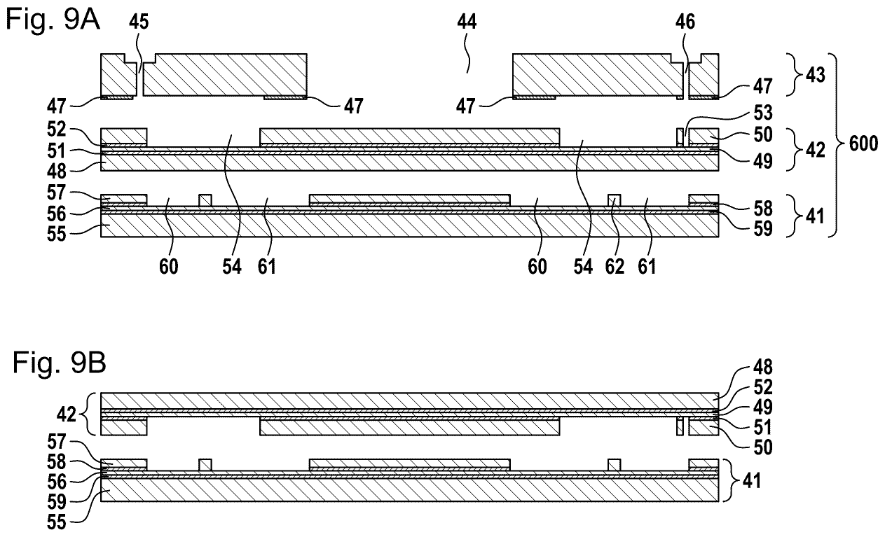

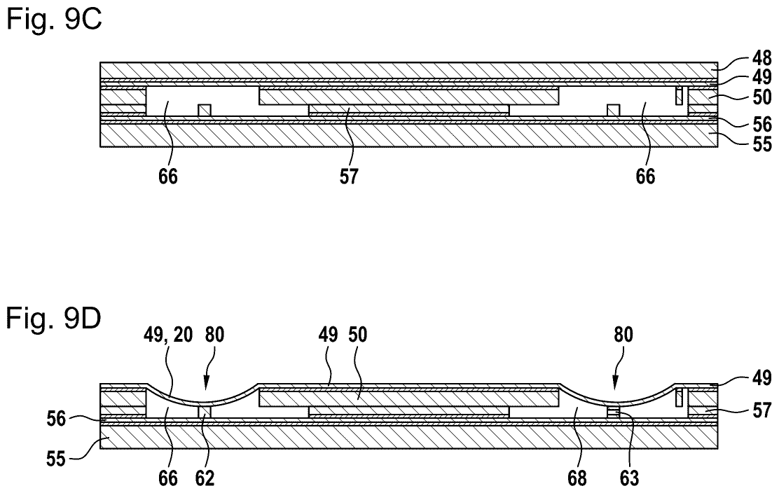

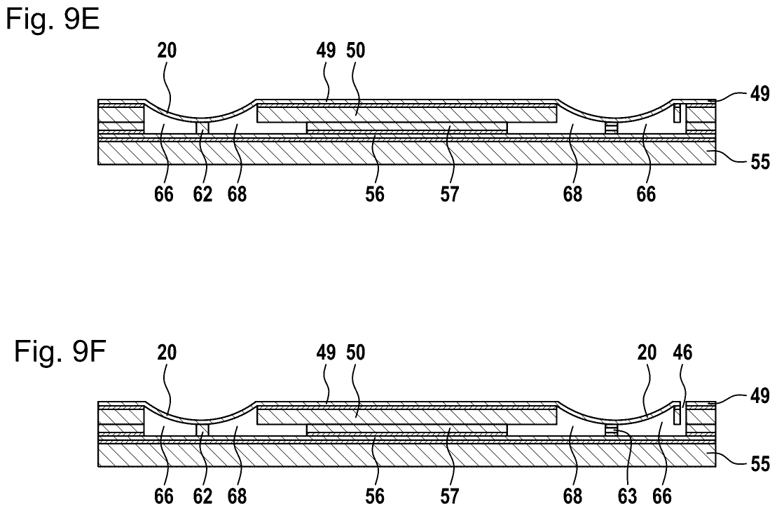

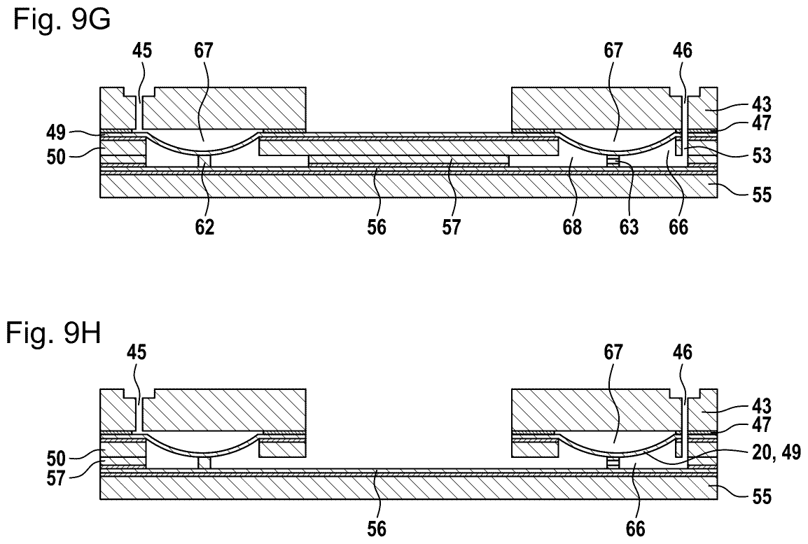

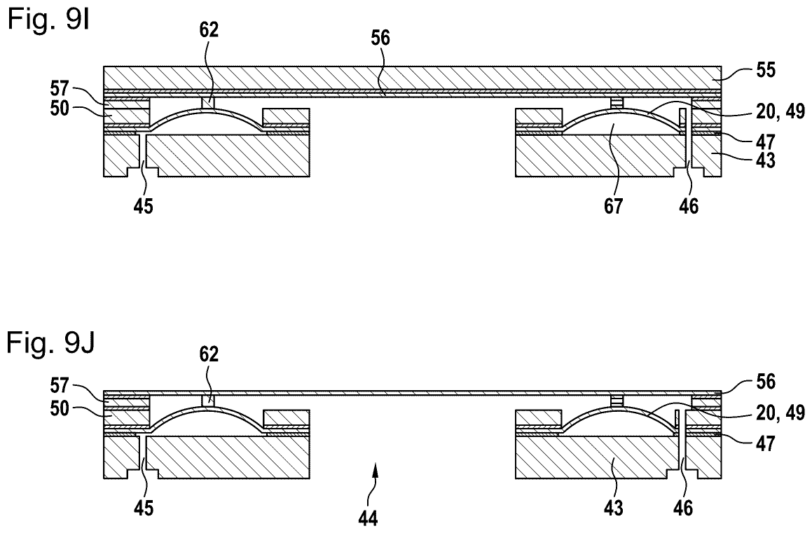

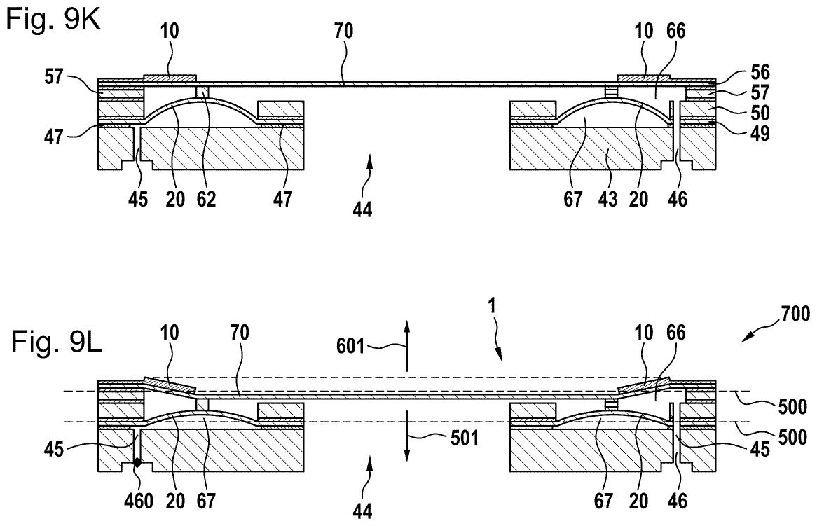

With reference to FIGS. 9A-9L, 11A, 11B, and 12, methods for producing membrane springs 1 are described, which can be permanently elastically preloaded and comprise two membrane spring elements 10, 20 mechanically coupled to one another. For this purpose, at least one of the membrane spring elements 10, 20 is provided with a two-dimensional, convex and/or concave curvature, wherein a first membrane spring element 10 preferably has a linear spring characteristic curve and a second membrane spring element 20 preferably has a nonlinear spring characteristic curve. The membrane spring elements 10, 20 are mechanically coupled to one another in such a way that the membrane spring 1 as a whole has a nonlinear characteristic curve. Spring characteristic curves of such membrane springs 1, which are formed by a mechanical coupling of membrane spring elements 10, 20 with linear (l) and nonlinear (nl) spring characteristic curves, are generally nonlinear in nature and can also be referred to as linear-nonlinear (lnl) spring characteristic curves.

The methods described here are in particular suitable for providing membrane springs 1 that have lnl spring characteristic curves and are made of silicon and in a wafer composite, for example in a layer structure 600 of a MEMS component 700 to be produced. The presented methods can in particular be combined with conventional production processes for producing further microelectromechanical functional elements, such as sensor elements or actuator elements.

By way of example, the figures schematically show methods for producing a membrane spring 1 with a two-dimensional curvature. It is understood that the presented methods are equally suitable for providing the aforementioned and below-mentioned membrane spring elements 10, 20 as individual components.

The method illustrated in FIGS. 1A to 1C for producing a membrane spring 1 or a membrane spring element 10, 20 using subtractive technology comprises the steps of:
providing a substrate 1000 made of a semiconductor material, for example silicon (cf. in particular FIG. 1A), wherein the opposite end-face surfaces of the substrate 1000 are referred to below as front side 1001 and rear side 10002;
removing material (also: material ablation) from the front side 1001 of the substrate 1000 and the rear side 1002 of the substrate 1000 in such a way that a membrane spring 1 or a membrane spring element 10, 20 with a two-dimensional, convex or concave curvature is provided (cf. in particular FIGS. 1B and 1C);

The removal of the material from the front side 1001 and the rear side 1002 of the substrate 1000 can take place simultaneously or in separate method steps, as shown in FIGS. 1B and 1C, for example.

The resulting geometry of the produced component can be designed almost arbitrarily using subtractive technology; in particular, a membrane thickness can be varied locally, for example in the radial direction and/or in the tangential direction.

In particular, it is provided to introduce local surface structuring, for example in the form of depressions, grooves or the like, radially symmetrically or rotationally symmetrically on the front and/or rear side 1001, 1002 of the membrane spring 1 or the membrane spring element 10, 20. In particular, it is thus possible to produce membrane springs 1 or membrane spring elements 10, 20 the geometries of which are comparable to disk springs of different variants and are, for example, slotted, locally reinforced and/or provided with other surface contours. On the basis of the surface structuring, the spring characteristic curves of the produced membrane springs 1 or membrane spring elements 10, 20 can be modified and in particular adapted to the technical application.

In the exemplary embodiment of FIGS. 1A to 1C, the semiconductor material is removed by means of laser ablation. Optionally, the surfaces produced by the material ablation can be remachined, in particular by means of isotropic etching, for example wet-chemically or by means of RIE (reactive ion etching). In this optional method step, any mechanical stresses and/or surface roughness still present after the laser treatment can advantageously be compensated.

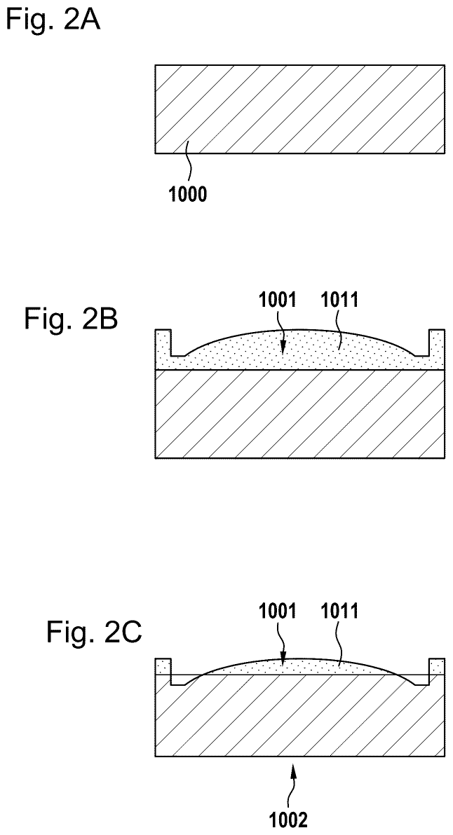

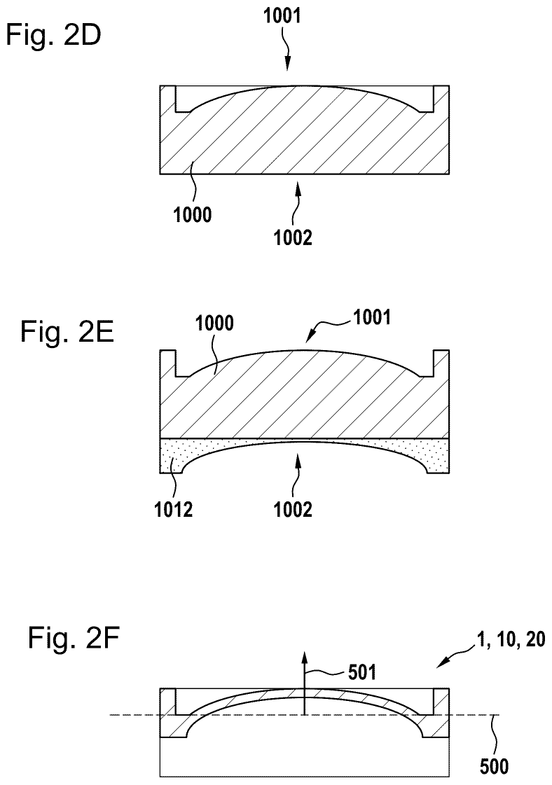

A further possibility for suitably removing the semiconductor material of the substrate 1000 from both the front side 1001 and the rear side 1002 is to apply a three-dimensionally structured etching mask 1011, 1012, in particular a polymer etching mask, as shown by way of example in FIGS. 2A to 2F. The shape of the etching mask 1011, 1012 is selected with regard to a defined etching selectivity, i.e., the ratio of the removal rate of the mask material to the removal rate of the semiconductor material of the substrate 1000, such that it is transferred into the semiconductor material by RIE etching, see in particular FIGS. 2B to 2F.

In the method illustrated in FIGS. 2A to 2F, the front side 1001 of the substrate 1000 is structured in a first method step by applying a first etching mask 1011 (cf. in particular FIGS. 2B to 2D), and the rear side 1002 of the substrate 1000 is structured in a second method step by applying a second etching mask 1012 (cf. in particular FIGS. 2E and 2F).

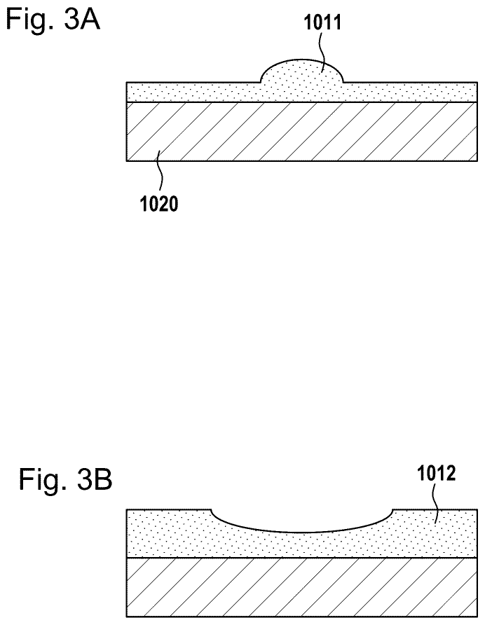

The etching masks 1011, 1012 can in particular be provided by dispensing resist, by means of grayscale lithography or by means of holographic lithography. The production of a suitable, three-dimensional etching mask 1011, 1012 can take place by means of replication in the wafer composite, as shown schematically in FIGS. 3A and 3B. For a true-to-shape transfer of the 3D structures of the mask into the semiconductor material, a selectivity as low as possible, close to the value 1, is advantageous, in particular during trench etching. The selectivity can be set specifically in a conventional manner using multiple process parameters.

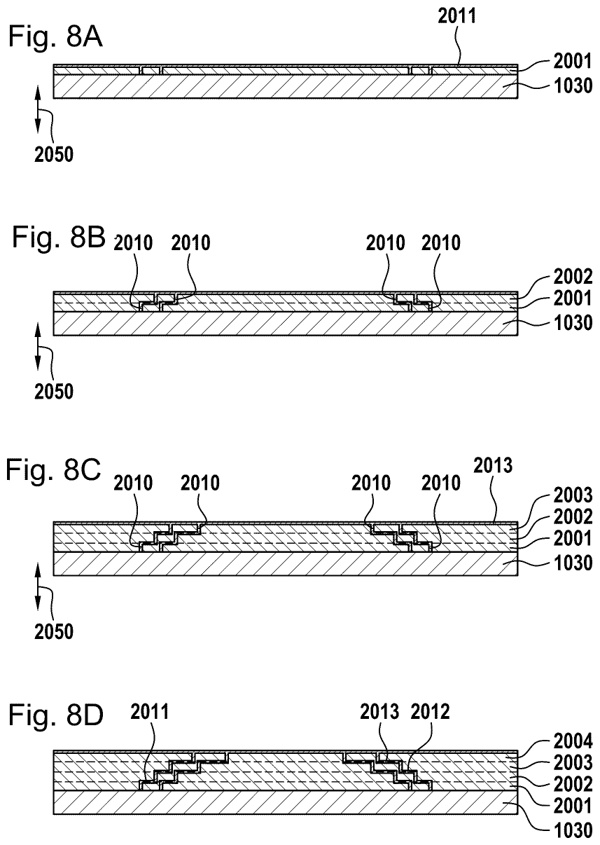

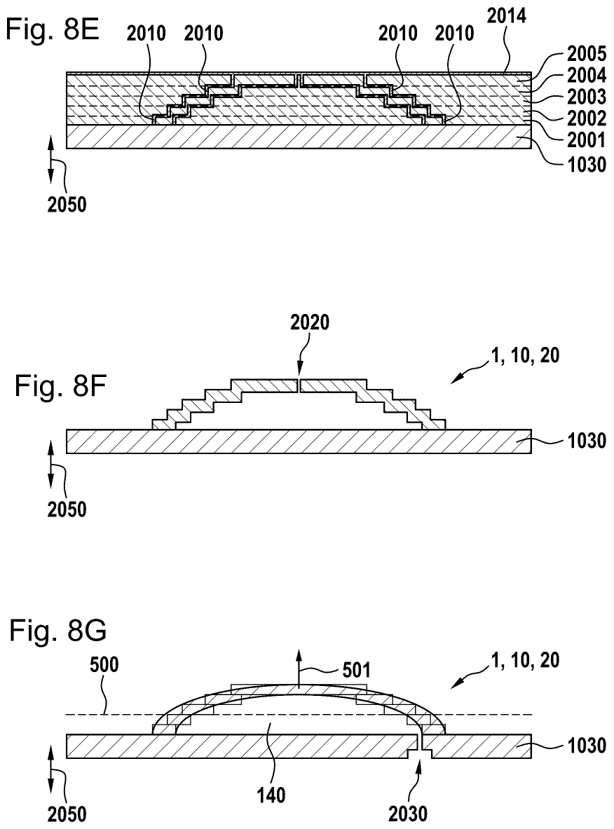

FIGS. 8A to 8C schematically illustrate the production of a membrane spring 1 or a membrane spring element 10, 20 using additive technology. The two-dimensionally convexly or concavely curved membrane spring 1 or the two-dimensionally convexly or concavely curved membrane spring element 10, 20 is produced by successively depositing individual layers 2001, . . . , 2005, which consist of a semiconductor material, preferably silicon or polysilicon. The layers 2001, . . . , 2005 or the silicon layers, as shown schematically in particular in FIGS. 8A to 8E, are deposited onto a substrate 1030 and, after the respective deposition, are structured by DRIE etching (deep reaction ion etching). Then, trenches 2010 are etched into the deposited layers 2001 to 2005 in parallel with the layer sequence direction 2050. After the respective structuring, the trenches 2010, or the trench regions etched into the deposited layers 2001, . . . , 2005, are filled with oxide. After the respective deposition process, an oxide layer 2011, . . . , 2014 is regionally applied to the previously deposited layer 2001, . . . , 2005 and is suitably structured.

The at least regionally convex or concave, two-dimensional curvature of the membrane spring 1 is formed in the additive manufacturing step by depositing regionally overlapping layers 1001, . . . , 2005. The geometry of the thus produced membrane spring 1 or membrane spring elements 10, 20 and the resulting spring characteristic curve can be predetermined by the thickness of the individual layers 2001, . . . , 2005, the overlap of the individual layers 2001, . . . , 2005, in particular in the layer sequence direction 2050, and/or by the structuring in the layers 2001, . . . , 2005. For this purpose, slots may, for example, be introduced in the radial direction. After the curved component 1, 10, 20 has been exposed, for example by means of XeF₂ etching, the cross-section thereof has a stepped structure corresponding to the thickness of the individual layers 2001, . . . , 2005, as shown in particular in FIG. 8F.

In a subsequent optional method step, as shown in FIG. 8G, smoothing takes place, for example by tempering the surface, in particular under a hydrogen atmosphere. This advantageously reduces any residual mechanical stresses still present.

In the method step of FIG. 8G, a production-related opening 2020 on the front side 1001 of the produced component is preferably sealed, in particular by means of laser treatment. It is optionally provided to introduce an access opening 2030 in the substrate 1030, in particular for applying pressure to a cavity 140 which adjoins the membrane spring 1 or the membrane spring element 10, 20.

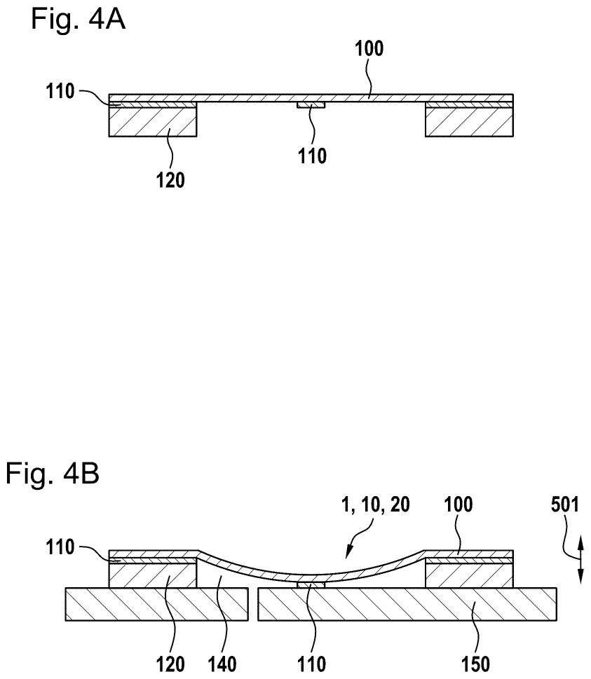

FIGS. 4A to 7B schematically illustrate the production of a membrane spring 1 or a membrane spring element 10, 20 using forming technology. In this case, a thin, typically silicon, layer 100 of a layer composite, in particular of an SOI wafer (SOI: silicon-on-insulator), is exposed. The layer 100 is arranged on a substrate 120, which is typically also made of silicon, and is separated therefrom by an intermediate insulation layer 110, in particular made of an oxide. The layer 100 is locally exposed, for example by trench etching from the rear side of the substrate 120. Subsequently, the insulation layer 110 on the rear side of the exposed layer 100 is completely or at least regionally removed.

Optionally, as shown in FIG. 4B, for example, a portion of the insulation layer 110 remains in a central region of the exposed layer 100, which provides a functional membrane 70 of the membrane spring 1 or of the membrane spring element 10, 20 after forming.

For forming, a pressure difference is established between the front side and rear side of the exposed layer 100, for example 1 bar ambient pressure on the front and vacuum on the rear side. In particular, a cavity 140 formed between the rear side of the exposed layer 100 and a further substrate 150 can be evacuated. In a hot process, optionally under a hydrogen atmosphere, the exposed layer 100 is plastically deformed under pressure into the membrane spring 1 or the membrane spring element 10, 20. In so doing, any remaining insulation layer 110 in the rear center of the membrane can be used as a mechanical stop, as shown in particular in FIG. 4B. The insulation layer 110 remaining in regions can also be used to limit or reduce the plastic deformation (“flow”) locally.

Before the hot process, the front side and/or rear side of the exposed layer 100 can be structured locally. In order to set the spring properties and to define zones with greater plastic deformation during the hot process, local depressions, such as locally thinned regions or the like, can be introduced. After cooling and after eliminating the pressure difference, a two-dimensionally curved membrane 1 or a two-dimensionally curved membrane spring element 10, 20 with reduced intrinsic mechanical stresses results.

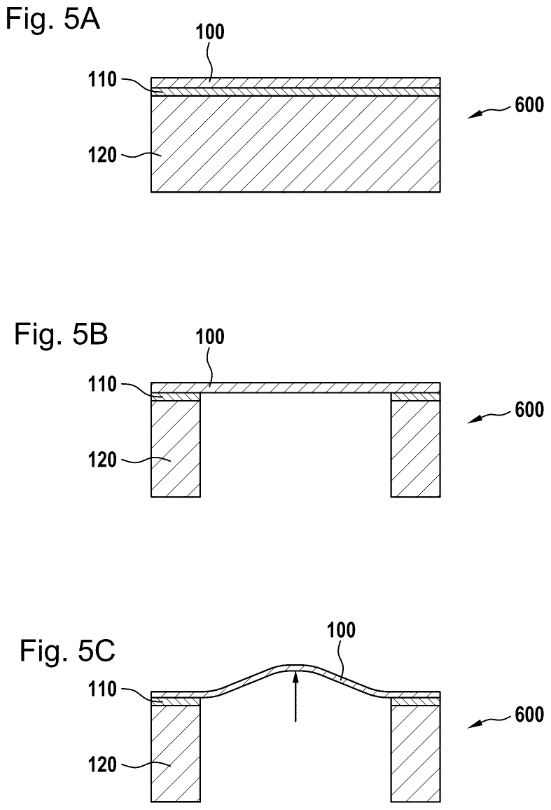

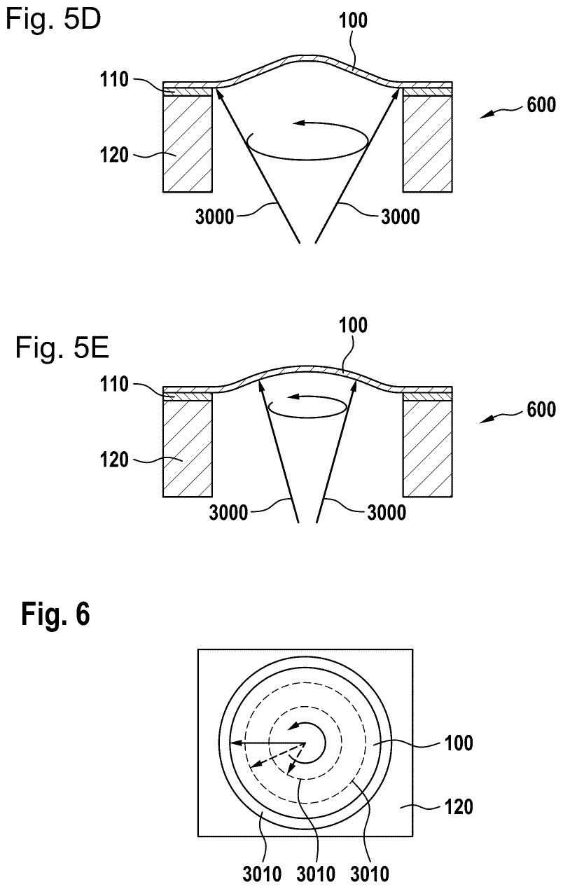

FIGS. 5A to 5E illustrate a method for producing the membrane spring 1 or the membrane spring element 10, 20, which comprises the following steps:
providing a layer structure 600, in particular SOI wafer, having a layer 100, in particular made of silicon, an insulation layer 110 and a substrate 120, cf. in particular FIG. 5A;
exposing the layer 100 in the layer structure 600, wherein the substrate 120 and the insulation layer 110 are regionally removed, cf. in particular FIG. 5B;
applying pressure to the exposed layer 100, wherein a pressure difference is established between the end faces of the exposed layer 100; and
plastically deforming the exposed layer 100 under at least local heating, cf. in particular FIGS. 5C to 5E.

The plastic deformation of the exposed layer 100 can be achieved by softening the material locally, in particular by means of laser treatment, as shown in FIGS. 5D, 5E, and 6, for example. The laser treatment optionally takes place under a hydrogen atmosphere. For plastically forming, the exposed layer 100 is deflected by applying pressure. The exposed layer 100 is locally heated in regions, preferably by means of laser radiation, so that it can be plastically deformed. The parameters of the laser radiation, such as the wavelength and/or the pulse duration, are selected such that the material of the exposed layer 100 can be heated efficiently and evenly. In order to couple the energy of the laser beam as uniformly as possible across the substrate thickness, absorption properties of the exposed layer 100 can optionally be set by means of a corresponding doping of the material, in particular the silicon.

The laser beam is repeatedly directed along trajectories 3010 onto the exposed layer 100 via a controllable optical deflection unit (scanner), as shown in FIGS. 5D, 5E, and 6, for example. With rapid repetition and sufficiently high energy input, the material of the exposed layer 100 heats up comparatively evenly along the trajectory 3010 so that it can deform when a temperature sufficient for plastic deformation is reached. The degree and position of the plastic deformation can be predetermined via the selected trajectory 3010 of the laser beam 3000 on the membrane surface and can thus be varied in particular in the tangential and/or radial direction, as shown in FIG. 6, for example.

Pulsed but also continuous laser radiation, in particular a continuous wave laser, is suitable for treating the exposed layer 100. The degree of local plastic deformation can also be set, for example, via the laser energy density, the duration of the irradiation and/or the pressure application. In a development, it is provided to regulate such parameters depending on the deformation measured in situ during the process, in order to bring about a desired deformation of the exposed layer 100 according to a predetermined, two-dimensional curvature. An advantage of this forming method is that the membrane is planar before the deformation, so that functional sensor elements or actuator elements, such as piezoresistive or piezoelectric elements, wiring levels and the like, can be produced on a planar wafer surface using the usual MEMS processes. However, these elements could be destroyed at the high temperatures that are typically necessary to plastically deform the exposed layer 100. The use of laser radiation advantageously makes a local temperature input on the exposed layer 100 to be formed possible, which is substantially limited to the irradiated region. The membrane spring 1 or the membrane spring element 10, 20 can thus be produced in a wafer composite or layer composite in such a way that destruction of the other functional elements of the MEMS component 700 to be produced can be largely avoided and waste is reduced.

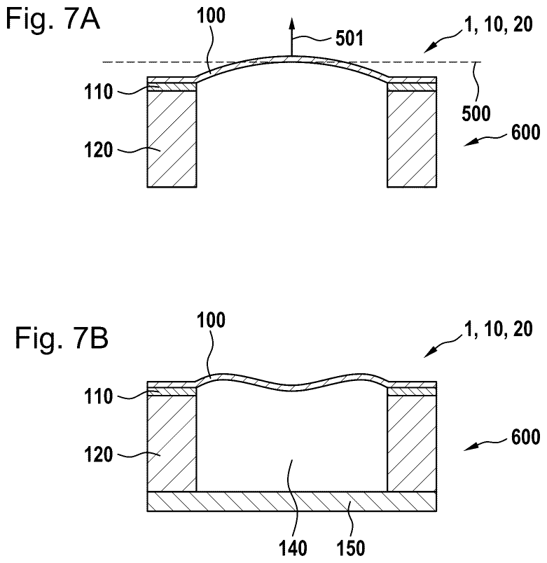

FIG. 7A shows the membrane spring 1 produced by forming, or the membrane spring element 10, 20 produced by forming, in a side view without an applied pressure difference. FIG. 7B accordingly shows the membrane spring 1 or the membrane spring element 10, 20 with a pneumatic preloading, wherein a cavity 140 is subjected to negative pressure or positive pressure. The cavity 140 is regionally delimited by the membrane spring 1 or the membrane spring element 10, 20 so that applying pressure can bring about elastic preloading. The pneumatic preloading of the membrane spring 1 or of the membrane spring element 10, 20 serves to set an operating point of the membrane spring 1 with respect to the spring characteristic curve, in particular in such a way that it is in an at least approximately linear spring characteristic curve range with a slight gradient.

FIGS. 9A to 9L show a method for producing a MEMS component 700 with a membrane spring 1 designed as a spring combination element, which comprises a first and a second membrane spring element 10, 20, which are mechanically coupled to one another. The membrane spring elements 10, 20 have two-dimensionally convexly or concavely curved portions and are mechanically coupled to one another in such a way that the resulting spring force 501 follows a nonlinear, in particular linear-nonlinear spring characteristic curve. Shown is a schematic layer structure and an example of a process sequence for the production of such a spring combination element with an integrated device for preloading the membrane spring elements 10, 20 mechanically coupled to one another. The MEMS component 700 may, for example, be a MEMS loudspeaker.

In a first step, a first, a second and a third wafer 41, 42, 43, in particular made of silicon, are provided, cf. in particular FIG. 9A.

The third wafer 43 is provided with a rotationally symmetrical through-opening 44 in the region of the functional membrane. Outside the through-opening 44, smaller, further through-openings 45, 46 are introduced into the third wafer 43. The further through-openings 45, 46 can be countersunk on the front side with respect to the surface of the third wafer 43.

On the rear side of the third wafer 43, a bonding agent 47 for hermetically bonding is optionally applied in regions. Wafer bonding can take place using conventional MEMS processes and equipment, such as seal glass bonding or eutectic bonding.

In the illustrated exemplary embodiment, the second wafer 42 is composed of three layers 48, 49, 50, wherein the thickness of the first layer 48 of the second wafer 42 is preferably selected to ensure the handling of the second wafer 42 during the production method.

The second layer 49 and/or the third layer 50 of the second wafer 42 are optionally polysilicon layers. Thin oxide layers 51, 52 are introduced between the layers 48, 49, 50. The curved second membrane spring element 20 with a nonlinear characteristic curve is produced from the second layer 49 of the second wafer 42. The thickness of the second layer 49 of the second wafer 42 is preferably designed according to the desired spring characteristic curve. The thickness of the third layer 50 of the second wafer 42 defines the desired curvature height of the second membrane spring element 20, which is formed from the second layer 49. A recess 53 is introduced into the third layer 50 of the second wafer 42 at the position of the further through-opening 46. A further, rotationally symmetrical, in particular annular, recess 54 defines the clamping or the width of the second membrane spring element 20.

The first wafer 41 is composed of three layers 55, 56 and 57. The thickness of the first layer 55 of the first wafer 41 is preferably selected to ensure the handling of the first wafer 41 during the production method. The second layer 56 and/or the third layer 57 of the first wafer 41 optionally consist of polysilicon. Thin oxide layers 58, 59 are introduced between the layers 55, 56, 57. The first membrane spring element 10 with a linear characteristic curve is produced from the second layer 56 of the first wafer 41. The thickness of this second layer must be designed according to the desired spring characteristic curve. The thickness of the third layer 57 of the first wafer 41 defines the desired curvature height of the first membrane spring element 10, which is formed from the second layer 56. Annular recesses 60, 61 are introduced into the third layer 57. The recess 60 defines the clamping or the width of the first membrane spring element 10 with a linear characteristic curve. A remaining, in particular annular, connecting element 62 between the recesses 60, 61 serves to mechanically connect or mechanically couple the first and the second membrane spring element 10, 20 to one another. The connecting element 62 is interrupted at least at one position along its circumference (cf. in particular FIG. 9D) by a transverse opening 63.

The third layer 57 of the first wafer 41 and the third layer 50 of the second wafer 42 are aligned to face one another and are bonded to one another (cf. in particular FIGS. 9B and 9C). Suitable direct bonding processes, preferably with heat input, are sufficiently known to a person skilled in the art. After cooling, a negative pressure, preferably a vacuum, is established in a concentrically arranged cavity 66 formed by the recesses 60, 61, 54.

In a subsequent method step, the first layer 48 of the second wafer 42 is removed (cf. in particular FIG. 9D). After removal of the first layer 48 of the second wafer 42, the exposed portion of the second layer 49 curves in the direction of the cavity 66 due to the applied pressure difference. Curving continues until the exposed portion of the second layer 49 touches the connecting element 62, wherein the second layer 49 is formed into the second membrane spring element 20 and a partial region 68 of the cavity 66 is separated from the connecting element 62. This method step is preferably supported by tempering under a hydrogen atmosphere.

In a further method step, a central region 80 of the second layer 49 formed into the second membrane spring element 20 is firmly connected to the connecting element 62. This takes place locally, for example, by means of laser welding (cf. in particular FIG. 9E).

Subsequently, the cavity 66 is ventilated by locally removing the second layer 49 of the second wafer 42 in the region of the through-opening 46 (cf. in particular FIG. 9F). Since the partial region 68 of the cavity 66 is connected to the environment via the transverse opening 63, the ambient pressure is established in the partial region 68.

FIG. 9G shows the wafer stack composed of the first, second and third wafers 41, 42, 43 after bonding. In the wafer composite, an annular, hermetically sealed cavity 67 is thereby produced between the third wafer 43 and the curved membrane spring element 20. The through-opening 45 is positioned and dimensioned such that it forms an access opening to a cavity 67. The through-opening 46 is located above the recess 53 and forms the access opening to the cavity 66 with partial region 68. In the region of the through-opening 44 of the third wafer 43, the layers 49, 50, 57 are regionally removed by means of trench etching and oxide etching (cf. in particular FIG. 9H).

FIGS. 91, 9J and 9K show the removal of the first layer 55 of the first wafer 41 and the formation of functional sensor elements or actuator elements on the exposed, sealed and planar second layer 56 of the first wafer 41.

The second layer 56 of the first wafer 41 forms both a functional membrane 70 and the first membrane spring element 10 with a linear spring characteristic curve. The first membrane spring element 10 with a linear spring characteristic curve is mechanically coupled to the curved membrane spring element 20 via the connecting element 62 and thus, as a whole, forms the membrane spring 1.

The cavity 67 is evacuated via the through-opening 45 and subsequently permanently and hermetically sealed by a seal 460 by means of a laser process, in particular laser reseal (cf. in particular FIG. 9L). The thereby produced pressure difference between the cavities 67 and 66/68 causes a vertical preloading of the membrane spring 1, which is formed as a spring combination element by the first and the second membrane spring element 10, 20. Due to the clamping of the membrane spring 1 at its outer circumference, the functional membrane 70 is displaced as a whole in the layer sequence direction, which corresponds to the first direction 601. The mechanical restoring force of the combined membrane spring elements 10, 20 is in force equilibrium with the pressure force due to the pressure difference inside and outside the cavity 67. After deflection of the membrane spring 1, it preferably has a reduced spring stiffness and the functional membrane 70 thus has a soft suspension.

The first membrane spring element 10 of the MEMS component 700 is mechanically connected at its outer circumference to the layer structure 600 and furthermore to the second membrane spring element 20 in such a way that the functional membrane 70 suspended on the inner circumference of the first membrane spring element 10 is movably guided along a spring path parallel to the first direction 601. The annular second membrane spring element 20 of the MEMS component 700 is clamped on both sides in order to impart a substantially linear-nonlinear or nonlinear force depending on the deflection. The second membrane spring element is mechanically connected to the layer structure 600 both at its inner circumference and at its outer circumference and is mechanically connected to the first membrane spring element 10 in an intermediate, two-dimensionally curved region. The first membrane spring element 10 has a substantially linear characteristic curve so that the spring characteristic curve of the coupled membrane spring substantially follows a nonlinear spring characteristic curve, in particular a linear-nonlinear spring characteristic curve, with a range of a small positive or negative spring constant, in particular after preloading.

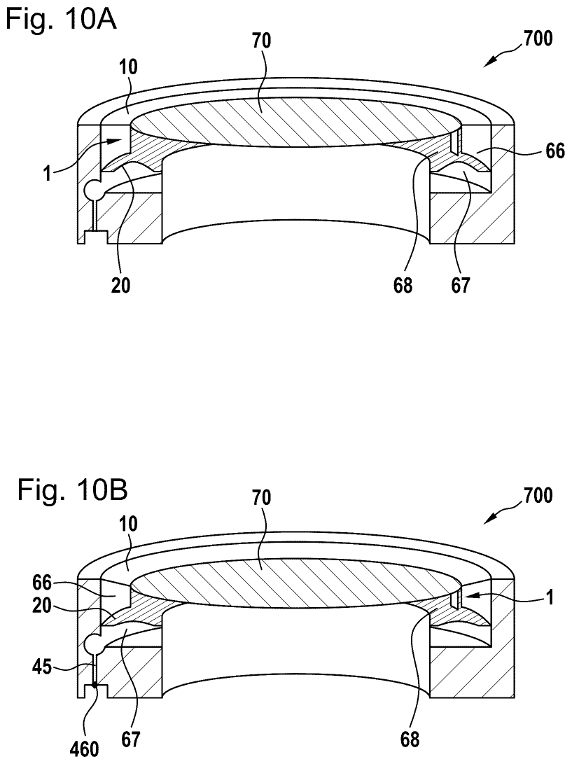

FIGS. 10A and 10B show a perspective view of the MEMS component 700, which was produced according to the method shown in FIGS. 9A to 9L. In this production method, the curved second membrane spring element 20 is produced by means of forming. The forming process is integrated into the overall process flow.

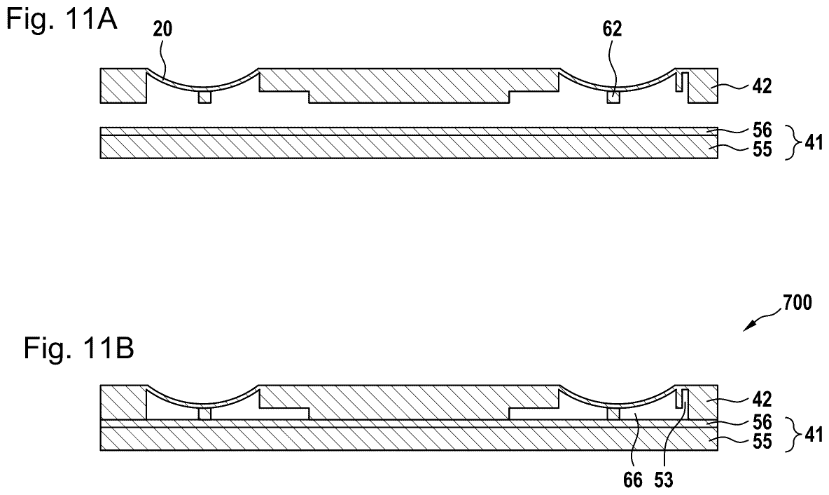

Alternatively, the curved second membrane spring element 20 can be produced in the second wafer 42 by means of additive or subtractive technology as a separate component, in particular by means of one of the methods shown in FIGS. 1A to 8G, and can subsequently be bonded to the first wafer 41. Such a production is illustrated schematically in FIGS. 11A and 11B, wherein the process steps according to FIGS. 9E to 9L follow largely unchanged. For bonding the first wafer 41 and the second wafer 42, other methods, such as eutectic bonding, can also be used in this process alternative.

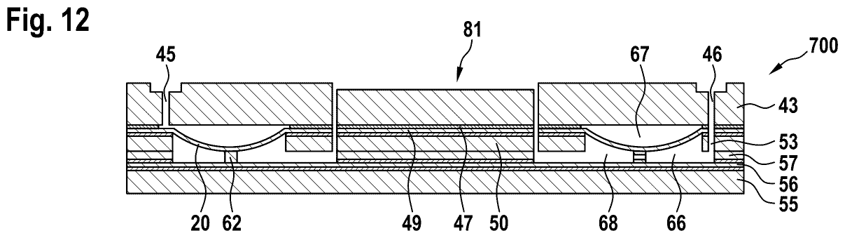

FIG. 12 shows an embodiment in which a large mass is fastened to the functional membrane 70. This substantially corresponds to the process state of FIG. 9H with a modified third wafer 43, which has a depression 81 instead of the through-opening 44. A large mass and a soft but robust spring suspension is advantageous, for example, when using such a MEMS component 700 as an energy harvester.

The production methods shown are inter alia characterized by the following features:
producing a two-dimensionally curved second membrane spring element 20 with a nonlinear spring characteristic curve;
producing a first membrane spring element 10 with a linear spring characteristic curve;
establishing a mechanical connection between the first membrane spring element 10 and the second membrane spring element 20, optionally via a connecting element 62, to form a membrane spring 1, which corresponds to a linear-nonlinear spring combination, on which a functional membrane 70 is suspended;
producing a hermetic cavity 67 below the membrane spring element 20 and a pneumatic half-space or at least one cavity 66, 68 above the membrane spring element 20 in such a way that a pressure difference between the cavities 67 and 66/68 causes preloading of the membrane spring element 20;
applying functional layers to the planar, non-deflected functional membrane 70 and/or to the membrane spring element 10;
establishing a pressure difference between the pneumatic cavities 67 and 66/68 above and/or below the membrane spring element 20, in particular by evacuating the cavity 67 or temporarily evacuating the cavities 66, 68 via through-openings 45, 46.
producing the preloading of the membrane spring 1 formed as a spring combination element, in such a way that the deflection reduces the joint spring stiffness and the operating point is thus placed in a spring characteristic curve range with a small gradient;
permanently sealing the cavity 67, for example in the evacuated state, which corresponds to establishing permanent preloading of the membrane spring 1.

1-14. (canceled)

15. A microelectromechanical system (MEMS) component including a MEMS actuator or sensor, comprising:
a micromechanical membrane spring including a first membrane spring element and a second membrane spring element, the membrane spring having an at least regional, convex or concave, two-dimensional curvature, wherein the first membrane spring element is mechanically coupled to the second membrane spring element in such a way that a resulting spring force of the membrane spring is imparted by the first and second membrane spring elements, wherein the micromechanical membrane spring is integrated into a layer structure of the MEMS component in such a way that the resulting spring force of the membrane spring acts substantially in a layer sequence direction of the layer structure, wherein a device for preloading the membrane spring is configured to set an operating point of the membrane spring with respect to a spring characteristic curve using permanent elastic deflection of the membrane spring, in such a way that the operating point is in an at least approximately linear spring characteristic curve range of the membrane spring with a slight gradient.

16. The MEMS component according to claim 15, wherein the first membrane spring element is mechanically coupled to the second membrane spring element in such a way that the resulting spring force follows a nonlinear spring characteristic curve.

17. The MEMS component according to claim 15, wherein the first membrane spring element is configured to generate a spring force which follows a linear characteristic curve, and the second membrane spring element is configured to generate a spring force which follows a nonlinear spring characteristic curve.

18. The MEMS component according to claim 15, wherein, for generating the resulting spring force, the first membrane spring element is mechanically connected in a central region of the second membrane spring element.

19. The MEMS component according to claim 15, wherein the first and second membrane spring elements are substantially annular and the first and second membrane spring elements are arranged concentrically with one another.

20. The MEMS component according to claim 15, wherein the first and/or the second membrane spring element includes silicon.

21. The MEMS component according to claim 15, wherein the preloading device includes at least one cavity which is subjected to negative pressure or positive pressure and which is delimited at least regionally by the first and/or second membrane spring element.

22. The MEMS component according to claim 15, wherein the first membrane spring element is mechanically connected at an outer circumference to the layer structure and is connected to the second membrane spring element in such a way that a functional membrane suspended on an inner circumference of the first membrane spring element is movably guided along a spring path parallel to the layer sequence direction.

23. The MEMS component according to claim 15, wherein the second membrane spring element is mechanically connected at its inner circumference and at its outer circumference to the layer structure and is mechanically connected to the first membrane spring element in an intermediate, two-dimensionally curved region.

24. A method for producing a membrane spring for a microelectromechanical system (MEMS) component, the MEMS component including a micromechanical membrane spring including a first membrane spring element and a second membrane spring element, the membrane spring having an at least regional, convex or concave, two-dimensional curvature, wherein the first membrane spring element is mechanically coupled to the second membrane spring element in such a way that a resulting spring force of the membrane spring is imparted by the first and second membrane spring elements, wherein the micromechanical membrane spring is integrated into a layer structure of the MEMS component in such a way that the resulting spring force of the membrane spring acts substantially in a layer sequence direction of the layer structure, wherein a device for preloading the membrane spring is configured to set an operating point of the membrane spring with respect to a spring characteristic curve using permanent elastic deflection of the membrane spring, in such a way that the operating point is in an at least approximately linear spring characteristic curve range of the membrane spring with a slight gradient, the method comprising:
producing the at least regional, convex or concave, two-dimensional curvature of the membrane spring including an additive or subtractive or forming manufacturing step.

25. The method according to claim 24, wherein the production of the at least regional, convex or concave, two-dimensional curvature of the membrane spring in the forming manufacturing step takes place in the layer structure of the MEMS component in such a way that an at least partly exposed layer of the layer structure is subjected to pressure and plastically deformed.

26. The method according to claim 25, wherein the partly exposed layer is heated locally by laser radiation, during the plastic deformation.

27. The method according to claim 24, wherein a mechanical connection of a first membrane spring element to a second membrane spring element of the membrane spring takes place by laser welding.

28. The method according to claim 24, wherein, for the permanent elastic preloading of the membrane spring, at least one cavity introduced into the layer structure is subjected to negative pressure or positive pressure and is sealed in a gas-tight manner, wherein the cavity is delimited at least regionally by the first and/or second membrane spring element.
